(19) United States
(12) Patent Application Publication
(10) Pub. No.: US 2008/0193327 A1
(43) Pub. Date: Aug. 14, 2008

(54) Device For The Treatment Of A Gaseous Medium With Plasma And Method Of Protecting Such A Device Against Inflammation And/Or Explosion

(75) Inventor: Christian Vauge, Paris (FR)

Correspondence Address: SHOEMAKER AND MATTARE, LTD, 10 POST OFFICE ROAD - SUITE 110, SILVER SPRING, MD, 20910, US

(73) Assignee: ASKAIR TECHNOLOGIES AG, Zurich (CH)

(21) Appl. No.: 11/574,456

(22) PCT Filed: Aug. 10, 2005
(86) PCT No.: PCT/EP05/53926

§ 371 Date: Mar. 14, 2007

(30) Foreign Application Priority Data
Aug. 31, 2004 (EP) 04020619.5

(51) Int. Cl. B03C 3/02; B03C 3/68; B03C 3/82; H05K 13/00

(52) U.S. Cl. 422/4; 422/186.04; 422/121; 29/729

(57) ABSTRACT

The invention is related to an inflammation- and explosion-protected plasma-generating device (1) for the treatment of air, wherein the plasma is at least partially encased by a wire mesh, the wire mesh being dimensioned suchlike to allow for prevention of a flame to escape the housing. The invention is especially useful in order to fulfill the safety and security requirements for aviation purposes, especially civil aircrafts.

The present invention is related to a plasma-generating device, the use of such a device for treating a gaseous medium and a method of protecting such a device against inflammation and/or explosion.

Various methods of plasma generation and a vast variety of applications of such plasmas are known in the art, e.g. reviewed by Bogaerts et al., Spectrochimica Acta Part B 57 (2002) 609-658.

Corona discharge plasma has been suggested for the destruction of airborne microbes and chemical toxins, e.g. by U.S. Pat. No. 5,814,135. The device according to U.S. Pat. No. 5,814,135 possesses a point-to-grid geometry of the plasma-generating section, wherein either the positive or negative pole of a power supply is connected to the point; thus, a positive or a negative corona plasma is generated. A major drawback of such devices is the significant production of nocuous emissions such as ozone (O₃), nitric oxides (NOₓ), etc., which is only hardly to keep below critical values; moreover, electric efficiency and the achieved sterilizing effects are mostly not sufficient. Additionally, especially corona plasmas are highly non-uniform and unstable, thus allowing for a significant amount of contaminants to pass such devices without being eliminated.

Especially for aviation purposes, various high national and international laws and standards (e.g. EU law (regulations and directives) and the Joint Aviation Requirements (JAR) of the Joint Aviation Authorities (JAA)) have to be met with respect to inflammation- and explosion protection. Thus, plasma-generating devices as outlined above have to meet these standards when applied e.g. to civil aircrafts: if e.g. kerosene would get in contact with a plasma-generating device, an inflammation or explosion must not transmit outside of the plasma-generating device.

It is thus an object of the present invention to overcome at least some of the above-mentioned drawbacks, i.e. to provide a device and a method for treating a gaseous medium, that fulfils the safety and security requirements of especially civil aircrafts, especially with respect to inflammation and/or explosion protection, which is more efficient and enables for a better sterilizing effect.

These objects are met by a plasma-generating device, a method of treating a gaseous medium such as biologically or otherwise contaminated air with at least one plasma-derived reactive species and the use of both the device and the method for the sterilization of the gaseous medium according to the independent claims.

The plasma-generating device according to the invention comprises a housing, wherein a plasma is at least partially encased low for prevention of a flame to escape the housing. It is known to use wire mesh to shield a flame especially in ancient coal miner's safety lamps. However, it was surprisingly found that such a mesh can also be advantageously used in flow-through plasma chambers with a stream of air passing through the device. Most surprisingly, even the very high national and international laws and standards for aviation purposes can be met by a plasma-generating device equipped with a wire mesh according to the invention.

Preferably, the housing is configured as a flow-through housing, comprising an inlet and/or an outlet, thus allowing for the incorporation of such a device in air circulation devices such as air-conditioning units or the like.

According to an especially preferred embodiment, the wire mesh is made of or essentially comprises metal, e.g. iron or copper. The metal needs to dissipate the heat, when a flame comes in contact with the wire, thus a high thermal conductivity of the metal is especially preferred. The spaces between the wires of the mesh have to be sufficiently wide to allow for a suitable air flow, but must be small enough to allow for sufficient dissipation of heat. Thus, the space between the wires preferably does not exceed 0.2 cm, more preferably 0.15 cm, most preferably 0.1 cm.

The plasma-generating device according to the invention may preferably comprise (a) at least one first plasma-generating section, wherein at least one first plasma is generated; and (b) at least one second plasma-generating section, wherein at least one second plasma is generated. The device may be configured suchlike that at a given point of time said first and said second plasmas are of different polarity. Preferably, said first and said second plasma are of different polarity at any time the device is working; however, for specific needs or applications, the device may also be powered suchlike that both plasmas are not at any time of different polarity; e.g. a first plasma may be maintained in its polarity, while the second plasma is alternating in polarity, or vice versa. It is preferred that both the first and the second plasma are operating at ambient, approximately one atmosphere of pressure.

Preferably, both the first and the second plasma are based on the same general principle; most preferably, although not limited thereto, both the first and the second plasma are corona discharge plasmas, that are known in the art to be applicable at ambient pressure.

According to an alternative embodiment of the present invention, the plasma-generating device comprises at least one plasma-generating section, wherein a plasma is generated between electrodes, which are connected to a power supply. A conveyor, e.g. a fan or the like can be applied for controlling the conveyance-speed of a gaseous medium through the plasma-generating section; Two DC power supplies (or a split one) or an AC power supply is connected to said electrodes in order to generate plasmas of different polarity, wherein the AC power supply (or the DC power supplies, respectively) operates with a frequency that is adapted to the conveyance-speed suchlike that substantially all of the gaseous medium is subjected to both said plasmas of different polarity. Taking into account the phenomena of alternating electric wind generated by the alternating plasmas, suitably coordinated settings of conveyance-speed and frequency of the AC power supply need to be determined empirically; however, this can be easily achieved by routine experiments. According to this embodiment, one single plasma-generating section, comprising one single pair of plasma-generating electrodes is sufficient to carry out the present invention. However, it is possible and preferred, to arrange a plurality of plasma-generating section to subsequently contacting the gaseous medium therewith.

Both positive and negative corona discharge plasmas are known in the art. In general, corona discharges occur between a first electrode possessing a small radius of curvature, e.g. a tip, filament, wire, etc., commonly referred to as the active electrode, and a second electrode possessing a larger radius of curvature or even a flat electrode, e.g. a flat surface, a cylinder, a grid, or the like, commonly referred to as the counter-electrode. A high voltage in the range of several kV is usually applied, in order to achieve an electric field in the vicinity of the active electrode which is higher than the breakdown value for the gaseous medium (about 30 kV/cm in air). A corona discharge is called positive, when the active electrode is connected to the positive pole; a corona discharge is called negative, when the active electrode is connected to the negative pole.

Upon the high voltage being applied to the electrodes, a plasma (electrons, ions and neutral molecules) is generated in proximity (typically several millimeters to about 1 cm) to the active electrode. Upon initiation (i.e. ionisation of a molecule mediated by the electric field), charged particles are generated (ions and electrons) and rapidly accelerated, its direction depending on whether it is a positive or negative corona plasma. Upon collision with other molecules, e.g. oxygen or nitrogen of ambient air, molecules such as H₂O or the like, a plasma is generated with exponentially growing intensity (avalanche effect). The effects involved in the propagation of the plasma are commonly accepted as (a) recombination of electrons and ions, (b) excitation of molecules, mediated by photons or collisions with other particles, (c) attachment (and detachment) of neutral molecules to (from) charged particles (ions or electrons).

In general terms, three reactive species as understood here and henceforth are co-existing in especially corona plasmas, that need to be considered especially with respect to a sterilizing effect: (a) electric forces, originating ions and electrons; (b) UV-radiation; and (c) biocidal, especially bactericidal chemical species such as ozone.

Given the case of a positive corona plasma, the positive electrode rapidly attracts the light-weighted electrons and less rapidly repels heavier positive ions. During coexistence of both charges, both species (re-)combine, whereby UV-radiation is generated. This UV-radiation, in turn, is a new source of ionization inside the gaseous medium and at the surface of the electrodes, thus setting forth the avalanche. In simplified words, the positive corona plasma comprises two zones: a central luminous plasma zone and a second unipolar zone of positive ions, repelled from the positively charged electrode.

Given the case of a negative corona plasma, the electrons are heavily repelled from the negatively charged electrode, and are gradually slowed down by collisions with ambient molecules. These electrons possess too low energy to induce secondary ionisation. Secondary ionisation mainly occurs based on UV-photo ionisation and by the collision of the positive ions with the active electrode. The drifting electrons meanwhile attach to polar molecules, e.g. ambient water, thereby generating clusters; and/or attach to electronegative molecules, e.g. dioxygen (O₂) molecules, thereby generating superoxide (O₂⁻) and peroxide (O₂²⁻). In simplified words, the negative corona plasma comprises three zones: a plasma zone, a zone of photo-ionization of gas molecules and a unipolar zone of negative ions and clustered electrons.

Both types of corona discharge plasmas are known to generate significant amounts of hazardous emissions such as e.g. ozone (O₃), nitric oxides (NOₓ), etc.

A combination of plasmas of different polarity, preferably in near proximity alternatingly arranged, provides a synergistic effect: the unwanted outcome of hazardous emissions such as e.g. ozone (O₃), nitric oxides (NOₓ), etc. is significantly lowered, according to initial experiments, below the routine detection limits. This is supposably due to secondary ionisation at the active electrode, mediated by a photoelectric effect on this electrode. Moreover, the efficiency and the sterilizing effect is enhanced. Whereas the device according to U.S. Pat. No. 5,814,135 is reported to only decrease the number of colony-forming bacterial (E. coli) contamination by 90%, a device according to the invention typically allows for a remarkably improved sterilization efficiency.

The observed synergistic effect may be explained by theory, that positive ions of the unipolar, outer zone of the positive (corona) plasma are fed into the negative (corona) plasma section, thereby being attracted towards the negatively charged electrode, and thus giving rise to additional phenomena such as dissociative recombination and secondary ionization, supposably by a photoelectric effect on this electrode. In turn, negatively charged ions of the unipolar, outer zone of the negative (corona) plasma are fed into the positive (corona) plasma section, thereby being attracted towards the positively charged electrode, and thus once more giving rise to additional “seed” electrons, supposably by detachment of electrons and/or dissociative association, vide supra. The thuslike generated additional secondary ionization in both plasma-generating sections may explain the observed efficiency and the lowered emission of nocuous sub-stances in initial prototype experiments. Of course, exchange of positive ions and negative ions into either the negative (corona) plasma section or the positive (corona) plasma section can be effected by various approaches. For instance, such exchange may occur by preferably flow-aided diffusion from one plasma section to the other. Another approach is e.g. to change the polarity of the plasma itself e.g. from a negative to a positive one, thus subsequently attracting those ions to the central electrode, that were repelled before. Thus, the conveyance-speed of a gaseous medium (taking additionally into account the electric wind generated by the plasma(s)) and/or the voltage, preferably an AC voltage, is advantageously adapted suchlike to allow for a contact of substantially all of the gaseous medium with plasmas of different polarity in each plasma-generating section. In any case, the synergistic effect of combining both polarities of plasma contributes to an improved stability and uniformity of the overall plasma discharge, thereby decreasing the amount of contaminants that are passing the device drastically.

According to a preferred embodiment, the device comprises a chamber and/or an open space allowing for contacting a gaseous medium with said first and said second plasmas. Treatment in this respect includes decontaminating, disinfecting, sterilizing, etc. The chamber and/or the open space is to be understood as e.g. closed/closable treatment-box or the like for contacting a gaseous medium with the plasmas; or as to provide a means for device, comprising an inlet and an outlet. The counter-electrode is preferably configured suchlike to allow a gaseous medium to penetrate through the counter-electrode. Advantageously, the counter-electrode possesses apertures or the like, e.g. by means of a grid, that allows for flow-through of the gaseous medium.

According to another embodiment of the present invention, said first and second plasma-generating sections are each supplied by an AC current. If the supplied AC current is of opposite phase in both plasma-generating sections, plasmas of different polarity are generated in the first and the second plasma-generating section.

The supplied AC current is preferably of the same amplitude in both plasma-generating sections.

Preferably, current(s) are supplied ranging from DC to AC of e.g. up to several hundred kHz, e.g. 500 kHz; preferably in the range of about 50 Hz due to its common availability.

In another embodiment of the present invention, said first and second plasma-generating sections are supplied with DC current, largely simplifying the overall electrically-constructive needs.

Both in case of AC or DC voltage supplied to the first and the second plasma-generating section, the power supply needs to allow for the creation of a (constant or peak) electric field in the vicinity of the active electrode of about 30 kV/cm. Typically, electrodes are preferably arranged suchlike that voltages of about 12 kV can be supplied.

According to an especially preferred embodiment, said first and through housing, possessing an inlet and an outlet for a gaseous medium. According to the invention, the inlet and/or the outlet is/are equipped with a wire mesh, thus allowing for inflammation- and/or explosion protection by dissipation of heat in case of a flame getting in contact with the wire mesh. Integrated in a flow-through housing, especially both plasmas of different polarity get into contact preferably subsequently with a gaseous medium such as a gaseous medium to be treated. Such flow through housings easily allow for an integration of a device according to the invention into preferably circulating streams of fluid, especially gas streams, e.g. in air-conditioning systems, clean-rooms, refrigerators, stationary and portable sterilizers, etc.

The flow-through housing preferably allows for a division of incoming fluid into separate streams, wherein said separate streams are each contacted with at least one of said first or second plasmas. Division of the incoming fluid into separate streams is e.g. achieved by means of an upstream apertured plate or the like. Additional, subsequent guidance of the separated streams may be provided for specific applications or embodiments, but is not mandatory. The apertures may be provided e.g. by means of the apertured plate in any suitable shape (oblong, ellipsoidal, rectangular or the like, preferably circular). Sub-sequent further split-up and/or recombination of said separate streams may be advantageously applied according to specific embodiments. Depending on the specific application, however, care has to be taken to not hinder a sufficient flow-through of the substance to be treated; necessary and/or advantageous geometries of apertures can be easily ascertained by routine experiments. Separating an incoming stream of fluid into a plurality of smaller streams allows for efficiently contacting each of these plurality of smaller streams, either in parallel and/or in series, with a plurality of different plasma sections, preferably arranged directly in-line with each incoming small fluid stream, thus overcoming a drawback of especially corona plasma, i.e. the only little range-in-space of the generated plasma.

It is especially preferred that said first plasma section and said second plasma section are arranged alternatingly between inlet and outlet of the flow-through housing. Although one plasma of each plurality is generally sufficient, more than one pair of plasmas of opposite polarity may be arranged in one housing. Moreover, for special applications that can be met by special adaptation of the device, the first or second plasmas and/or plasma generating sections may be provided in excess number and/or intensity, mainly depending on the application. Such adaptations can be easily carried out by routine experiments.

According to another embodiment of the invention, at least one electrode of the first plasma-generating section is electrically coupled to, preferably formed in one piece with, at least one electrode of the second plasma-generating section. Especially in case of corona plasmas, this can be achieved e.g. by providing a hollow body, e.g. a hollow cylinder, as the positively charged, large counter electrode of a negative plasma. Additionally, this hollow body may possess a plurality of tips (or other geometric arrangements with a small diameter of curvature) on at least one end, thus at the same time acting as the positively charged electrode of a positive plasma in another plasma-generating section, or vice versa. It is evident to the person of routine skill in the art how to put into practice also different geometries, based on the above-mentioned bifunctionality of one electrode in general; e.g., a configuration only based on e.g. partially coaxially aligned hollow bodies, provided with tips or the like, is also a working alternative, which may yield in advantageous results in special applications.

It is, however, especially preferred, that the main flow-through direction of the device is approximately in parallel to the virtual line defining the shortest distance between the preferably tip-to-grid-like arranged electrode(s). Thus, flow-through direction and plasma generation are similarly directed, thereby allowing for an efficient contact of the gaseous medium with the plasma.

According to the invention, the device is advantageously used for the sterilization of a gaseous medium, e.g. biologically or otherwise contaminated air.

The device is preferably contained in or operatively connected to a closed and/or closable compartment. Such a compartment may be a room, a transportation vehicle of any kind, e.g. cars, busses, aircrafts, ships, trains, etc., or e.g. cabins within such transportation vehicles. The device is preferably used for inflammation- and/or explosion-sensitive application purposes. Most preferably, the device is used for the treatment of the ambient gaseous medium in the cabin of civil aircrafts. Preferably, the device is integrated into air circulation devices such as air-conditioning units or the like.

Moreover, the invention relates to a method of protecting a plasma-generating device, preferably contained in or operatively connected to a closed or closable compartment, the method comprising the steps of at least partially encasing a plasma by a wire mesh, the wire mesh being dimensioned suchlike to allow for prevention of a flame to escape the housing. Advantageously, this method easily allows for re-fitting of already installed plasma-generating devices by e.g. equipping the inlet and outlet of a flow-through housing of a plasma-generating device with a suitably dimensioned wire mesh.

Further objects, advantages and novel features according to the invention will become apparent from the following detailed description of a preferred embodiment, accompanied by the following schematical drawings:

FIG. 1: Corona discharge plasma device (prior art);

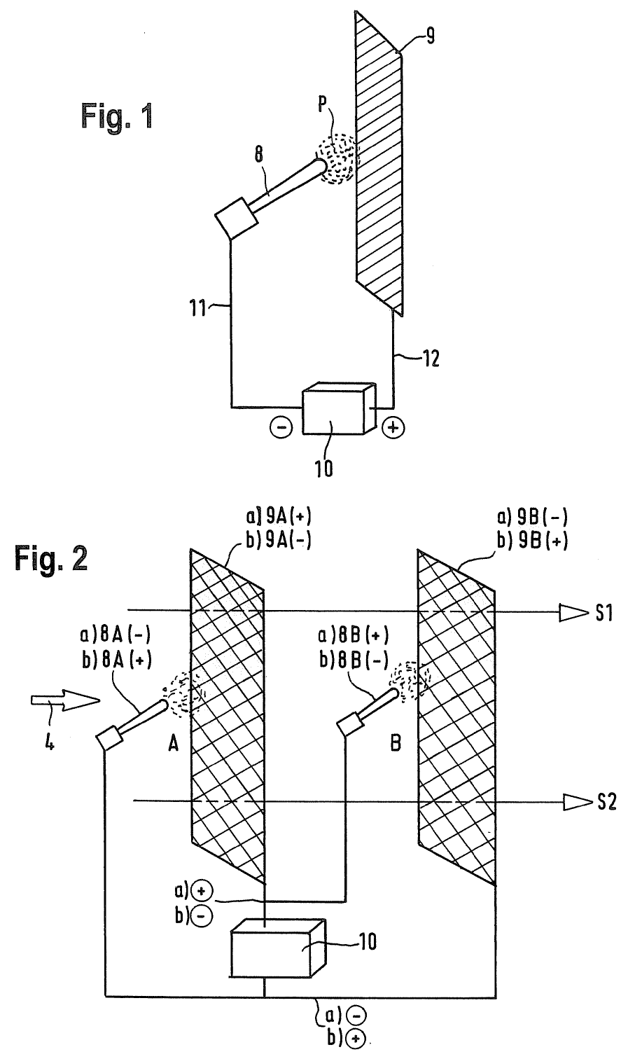

FIG. 2: Combination of corona discharges of different polarity in series within one device:
(a) negative-positive;
(b) positive-negative;

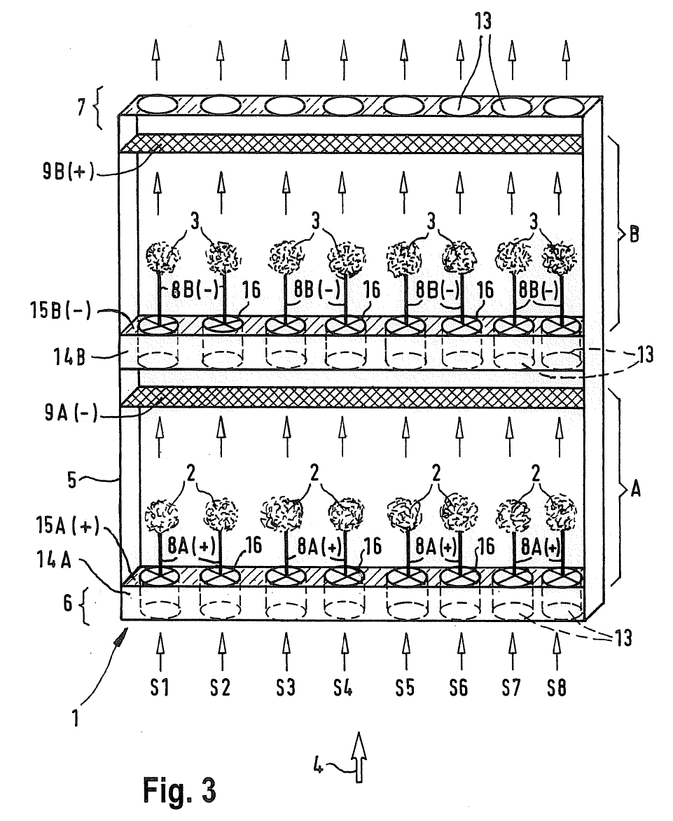

FIG. 3: Plasma-generating device with two plasma-generating sections;

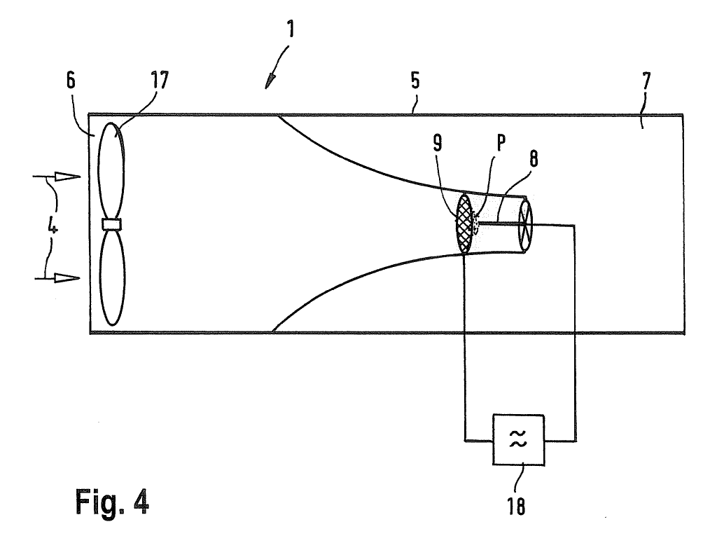

FIG. 4: Plasma-generating device with one plasma-generating section;

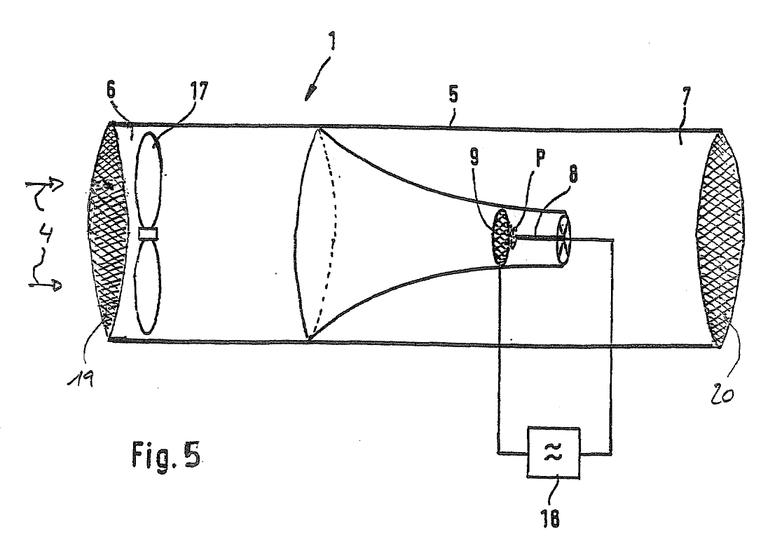

FIG. 5: Plasma-generating device with wire meshes at the inlet and outlet.

As shown schematically in FIG. 1, a corona discharge plasma as known in the art is typically generated between an electrode with a small radius of curvature, e.g. a tip 8, a spike or the like, and a counter-electrode 9, with a large radius of curvature, e.g. a flat surface, a grid, or the like. An electric power supply 10 is connected by electrically conducting means 11 and 12, e.g. metal wires, plates or the like to both electrodes 8 and 9, respectively. The power supplied by the power supply 10 is usually adapted suchlike to allow for the generation of an the active electrode 8, in order to generate a corona discharge P at about ambient, one-atmosphere of pressure. Upon the high voltage being supplied to the electrodes, a plasma P is generated around the electrode 8. As in the present example, the corona plasma P is called negative, as the negative pole of the power supply 10 is connected to the tip-like electrode 8. In contrast, and not shown explicitly in FIG. 1, a corona plasma is called positive, when the negative pole of the power supply 10 is connected to the tip-like electrode 8. Both negative and positive corona discharge plasmas are known per se.

As shown schematically in FIG. 2, two plasmas, here corona discharge plasmas, of different polarity are combined. According to situation a), two plasma-generating sections A and B are consecutively arranged. In the first plasma-generating section A, the electrode 8A(−) (letters indicate the plasma-generating section; signs according to the pole of the power supply 10 to which they are connected) allows for the generation of a negative corona discharge plasma, whereas the electrode 8B(+) of the second plasma-generating section B allows for the generation of a positive corona discharge plasma. Both the counter-electrodes 9A(+) and 9B(−) possess some kind of apertures that allow for a flow-through (indicated schematically by an arrow) of a gaseous medium, from the first plasma-generating section A to the second plasma-generating section B. For the sake of graphical clarity, only one of each electrodes 8A(−) and 8B(1) are shown explicitly; however, it is to be understood that a suitable amount of such electrodes is preferably provided in order to cover e.g. the flow-through diameter of the device. Both plasma-generating sections A and B may be supplied by either separate or one and the same power supply 10. As outlined above, either AC or DC voltage may be connected to both plasma-generating sections A and B. According to situation b), the polarity of both plasma-generating sections A and B may be altered, either by applying a DC voltage opposite to the configuration shown in situation a), or as an other half-wave of an AC current supplied to both plasma-generating sections A and B. If an AC current is applied, the frequency is preferably 50 Hz due to its common availability, although frequencies in the range from DC to e.g. several hundred kHz may be suitably applied.

FIG. 3 is a schematical drawing of a plasma-generating device 1. The device comprises a flow-through housing 5 of a suitable geometry, e.g. cylindrical, rectangular or the like. The flow-through housing 5 is electrically preferably insulated towards the exterior in order to prevent the user from getting in contact with the high voltages usually supplied to the device. The flow-through housing 5 further comprises an inlet 6 and an outlet 7, each preferably comprising apertures 13 of a suitable geometry, e.g. circular, ellipsoidal, oblong or rectangular, in order to separate a stream of an incoming gaseous medium 4 into partial streams S1, S2, etc. Preferably, apertures 13 of the inlet 6 are in-line arranged to apertures 13 of the outlet 7, and e.g. additional apertures 13 in between inlet 6 and outlet 7. The device comprises a first plasma-generating section A and a second plasma-generating section B. In the first plasma-generating section, plasma-generating electrodes 8A(+), possessing a tip with a small diameter of curvature, are arranged in-line with the apertures 13 of the inlet 6, in order to allow for a direct contact of plasmas 2 and the incoming streams S1, etc. of gaseous medium 4. In the present example, the tip-like electrodes 8A(+),8B(−) (letters according to the referenced plasma-generating section; signs according to the polarity of the voltage applied to the referenced electrode) are mounted on sustainers 16, in-line with the apertures 13. However, any other arrangement of electrodes pointing into a stream S1, etc., of a gaseous medium 4 may be suitably applied, such as electrodes mounted into side-walls of the flow-through housing 5, suitably arranged hollow-body, e.g. hollow-cylindrical electrodes or the like. A grid-like counter electrode 9A(−) is mounted upstream in order to allow for the generation of plasmas 2. In the present example, power is supplied to the electrodes 8A(+) via an electrically conducting layer 15A(+) and the sustainers 16. The insulating layer 14A may be either separate or may be part of the flow-through housing. If power is supplied to the plasma-generating section A (i.e. the positive pole of a power supply (not shown) connected to the electrodes 8A(+); the negative pole connected to the electrode 9A(−)), a positive plasma 2 is generated in the plasma-generating section A, and the streams S1 . . . S8 are subjected it. The streams S1 . . . S8 subsequently pass the apertures 13 of an insulating layer 14B and enter the plasma-generating section B. Exchange of reactive species from one plasma-generating section to another is also possible via apertures 13. Plasma-generating section B may be generally constructed analogous to plasma-generating section A, except the current supplied to the electrodes. Via electrically conducting layer 15B(−), the negative pole of a power supply (not shown) is connected to the tip-like electrodes 8B(−), arranged in-line with the corresponding apertures 13. As a counter-electrode, a grid-like electrode 9B(+) is arranged further upstream, followed by the outlet 7, preferably provided again with in-line arranged apertures 13. If power is supplied to the plasma-generating section B (i.e. the negative pole of a power supply (not shown) connected to the electrodes 8B(−); the positive pole connected to the electrode 9B(+)), a negative plasma 3 is generated in the plasma-generating section A, and the streams S1 . . . S8 are subjected to it. A gaseous medium 4 is, in total, subsequently contacted with two plasmas 2,3 of different polarity, giving rise to the advantageous characteristics as outlined above. Separate streams S1 . . . S8 are not mandatory, but may be advantageously provided especially in case of larger devices in order to allow for an efficient contact of plasma-generating electrodes 8A(+), 8B(−) and gaseous medium 4. Streams S1 . . . S8 may be e.g. generated by either apertured plates as in the present example, thus without any further guidance within the plasma-generating sections A,B. However, streams S1 . . . S8 may also be separated from each other e.g. by means of separating plates or the like.

FIG. 4 is a schematical drawing of another embodiment of a plasma-generating device 1. The device 1 comprises a flow-through housing 5 equipped with an inlet 6 and an outlet 7 in order to allow for a fluid to pass the device 1. A conveyor 17, e.g. a fan is provided in order to control and fine-tune the conveyance-speed of the gaseous medium 4 through the device. At least one pair of plasma-generating electrodes 8, 9 is provided. Advantageously, a focussing means such as a narrowing or the like for controlling the flow-through of the substrate may be applied; the electrodes 8, 9 are preferably arranged in direct proximity to the outlet of such focussing means. Upon appliance of an AC current by a power supply 18, an alternating plasma P of alternating polarity is generated between electrodes 8, 9. The conveyance-speed and the frequency of the AC current are coordinated suchlike to allow for the gaseous medium to be subjected to both polarities of the alternating plasma P. Although one single pair of plasma-generating electrodes is thus sufficient, it is to be understood that a plurality of alternatingly arranged plasmas is suitable to further improve the device according to the invention.

FIG. 5 is a schematical drawing of an inflammation- and explosion protected plasma-generating device 1 according to the invention. In contrast to the embodiment shown in FIG. 4, the flow-through housing 5 is equipped at the inlet 6 and outlet 7 with wire meshes 19 and 20, respectively. According to the invention, the wire meshes 19 and 20 are configured suchlike to allow for prevention of a flame to escape the flow-through housing 5. In case of e.g. kerosene getting in contact with the plasma P, when the device 1 is situated in an aircraft, the heat of a resulting flame is rapidly dissipated by the wire mesh, thus preventing inflammation and explosion outside of the device. Safety and security regulations of civil aircrafts can thus be met by a device 1 according to the invention with respect to inflammation and explosion protection. In order to provide sufficient heat dissipation, the wire mesh is made of or essentially comprises metal, e.g. iron or copper. The spaces between the wires of the mesh have to be sufficiently wide to allow for a suitable air flow, but must be small enough to allow for sufficient dissipation of heat. Thus, the space between the wires preferably does not exceed 0.2 cm ( 1/12 inches), more preferably 0.15 cm ( 1/18 inches), most preferably 0.1 cm ( 1/24 inches). Although explicitly shown here for a specific embodiment, virtually any plasma device may be (at least partially) encased by a wire mesh according to the invention to prevent a flame from escaping the housing.

1. Device for the treatment of a gaseous medium with a plasma, wherein the device comprises a flow-through housing, and wherein a plasma is at least partially encased by a wire mesh to prevent a flame from escaping the housing.

2. Plasma generating device according to claim 1, wherein the housing comprises an inlet and an outlet, and wherein the inlet and/or the outlet is/are equipped with the wire mesh.

3. Plasma generating device according to claim 1, wherein the wire mesh is made of or essentially comprises metal.

4. Plasma generating device according to claim 1, wherein the wire mesh is configured suchlike that the space between the wires does not exceed 0.2 cm.

5. Plasma-generating device according to claim 1, comprising at least one first plasma-generating section, wherein at least one first plasma is generated; and at least one second plasma-generating section, wherein at least one second plasma is generated; wherein at a given point of time said first and said second plasmas are of different polarity.

6. Plasma-generating device according to claim 1, comprising at least one plasma-generating section, wherein a plasma is generated between electrodes; a conveyor for controlling the conveyance-speed of a gaseous medium through the plasma-generating section; an AC power supply which is connected to said electrodes to generate alternating plasmas of different polarity; wherein the power supply operates with a frequency that is adapted to the conveyance-speed of the gaseous medium so that substantially all of the gaseous medium is subjected to both of said plasmas of different polarity at least once.

7. Device according to claim 1, wherein the device comprises a chamber and/or an open space allowing for contacting a gaseous medium with said first and said second plasmas.

8. Device according to claim 1, wherein said first and second plasmas are corona discharge plasmas.

9. Device according to claim 1, wherein said first and second plasma-generating sections are each supplied by an AC current.

10. Device according to claim 9, wherein the first plasma-generating section and the second plasma-generating section are supplied with AC current of opposite phase.

11. Device according to claim 9, wherein the first plasma-generating section and the second plasma-generating section are supplied with AC current of the same amplitude.

12. Device according to claim 9, wherein the frequency of the current (s) is/are in the range from DC to about 500 kHz of AC.

13. Device according to claim 5, wherein said first and second plasma-generating sections are supplied with DC current.

14. Device according to claim 8, wherein the difference in potential between the electrodes is adapted so that an electric field in the range of about 30 kV/cm is created nearby the electrode.

15. Device according to claim 5, wherein said first and said second plasma-generating sections are integrated in a flow-through housing, possessing an inlet and an outlet for a gaseous medium.

16. Device according to claim 15, wherein said flow-through housing allows for a division of incoming fluid into separate streams, and wherein said streams are each contacted with at least one of said first or second plasmas.

17. Device according to claim 15, wherein said first plasma-generating section and said second plasma-generating section are arranged alternatingly between inlet and outlet.

18. Device according to claim 5, wherein at least one electrode of the first plasma-generating section is electrically coupled to at least one electrode of the second plasma-generating section.

19. Device according to claim 18, wherein the electrode of the first plasma-generating section, which is electrically coupled to at least one electrode of the second plasma-generating section, is formed as a hollow body possessing a plurality of tips on at least one end of the hollow body.

20. A method of sterilizing a gaseous medium, comprising a step of passing said medium through a device according to claim 1.

21. Closed and/or closable compartment equipped with or connected to a device according to claim 1.

22. Compartment according to claim 21, wherein the compartment is a transporting apparatus such as an aircraft.

23. A method of protecting a plasma-generating device according to claim 1, which is situated in or connected to a closed and/or closable compartment, against inflammation and/or explosion, comprising the step of at least partially encasing a plasma by a wire mesh, the wire mesh being dimensioned so as to prevent a flame from escaping the housing.

24. A method according to claim 23, comprising the step of equipping an inlet and/or an outlet of a housing with a wire mesh.

25. A method according to claim 23, wherein the wire mesh is made of or essentially comprises metal.

26. A method according to claim 23, wherein the wire mesh is configured suchlike that the space between the wires does not exceed 0.2 cm.
